(19) United States
(12) Patent Application Publication
(10) Pub. No.: US 2008/0206992 A1
(43) Pub. Date: Aug. 28, 2008

(54) Method for manufacturing high flatness silicon wafer

(75) Inventor: Byung-Wook Nam, Buk-gu (KR)

Correspondence Address: GREER, BURNS & CRAIN, 300 S WACKER DR, 25TH FLOOR, CHICAGO, IL, 60606, US

(73) Assignee: Siltron Inc., Gumi-city (KR)

(21) Appl. No.: 12/005,665

(22) Filed: Dec. 27, 2007

(30) Foreign Application Priority Data
Dec. 29, 2006 (KR) 10-2006-0138487
Dec. 18, 2007 (KR) 10-2007-133510

(51) Int. Cl. H01L 21/463; H01L 21/465

(52) U.S. Cl. 438/691; 257/E21.483

(57) ABSTRACT

The present invention relates to a method for manufacturing a high flatness silicon wafer comprising (S21) slicing a silicon single crystal ingot to produce a wafer; (S22) chamfering an edge of the wafer sliced from the ingot; (S23) lapping the edge-chamfered wafer; (S24) etching the lapped wafer; (S25) grinding the etched wafer; (S26) slight-etching the ground wafer using an alkali aqueous solution to remove a surface degraded layer generated on the ground wafer; (S27) polishing one or two surfaces of the slight-etched wafer; and (S28) cleaning the polished wafer.

### BACKGROUND OF THE INVENTION

1. Field of the Invention

The present invention relates to a method for manufacturing a high flatness silicon wafer, and in particular, to a method for manufacturing a high flatness silicon wafer, which additionally performs a slight-etching process using an alkali aqueous solution before a polishing process to effectively remove a surface degraded layer generated during a grinding process in a series of wafer fabrication process including slicing, chamfering, lapping, etching, grinding and polishing processes, and to a method for manufacturing a high purity etching solution used in the method for manufacturing a high flatness silicon wafer.

2. Description of the Related Art

Conventionally, a silicon wafer is manufactured from a silicon single crystal through a series of processes. A conventional method for manufacturing a silicon wafer is described with reference to FIG. 1.

FIG. 1 is a flow chart illustrating the conventional method for manufacturing a silicon wafer.

Referring to FIG. 1, the method for manufacturing a silicon wafer comprises a slicing process for slicing a silicon single crystal ingot (S11), an edge-chamfering process for chamfering an edge of a silicon wafer obtained after the slicing process (S12), a lapping process (S13), an etching process (S14), a polishing process for polishing one or two surfaces of the silicon wafer (S15), and a cleaning process (S16). The silicon wafer is manufactured by sequentially performing these processes.

The above-mentioned processes may be partially modified or repeated according to purpose. Alternatively, other processes such as thermal treatment or grinding may be added or replaced. In particular, the etching process (S14) is intended to remove a surface degraded layer generated in mechanical processing such as the slicing process (S11), the chamfering process (S12) and the lapping process (S13). The etching process (S14) is generally a wet etching process. Conventionally, an acid etching process was mainly used because it is more advantageous in aspect of processing capacity of unit process. However, with recent trends toward finer gate design rule, an alkali etching process is used to meet the demands for flatness improvement and waviness prevention. However, after the alkali etching process is performed, the wafer surface may have pit damage of several μm to several tens μm. And, it is difficult to perform a metal cleaning process using a hydrofluoric acid. Further, wafer contamination may be occurred by inherent metal impurities of the alkali etching process. Therefore, attempts have been made to prevent the wafer contamination by impurities occurring in the wafer fabrication process.

As described above, it is general to perform the polishing process (S15) and the cleaning process (S16) after the etching process (S14). However, with trends toward minimization of an electrical device formed on the silicon wafer and finer layout of the silicon wafer, it is preferred that the silicon wafer has high flatness before the polishing process (S15). For this purpose, a grinding process is additionally performed between the etching process (S14) and the polishing process (S15) to grind one or two surfaces of the silicon wafer, thereby improving flatness of the silicon wafer. The polishing process (S15) follows the grinding process. Thus, the grinding process helps the polishing process (S15) to achieve high flatness with minimum polishing. However, a surface degraded layer may be generated on the silicon wafer in the grinding process, and if the surface degraded layer is not completely treated, it may result in deterioration of electrical characteristic of the electrical device to be formed on the silicon wafer.

Studies have been continuously made in the related art to solve the metal contamination problem by effectively removing the surface degraded layer generated in the grinding process that is performed between the etching process and the polishing process. In the above-mentioned technical background, the present invention was filed for a patent.

The present invention is designed to solve the above-mentioned problems of the prior art, and therefore it is an object of the present invention to provide a method for manufacturing a high flatness silicon wafer, which effectively removes a surface degraded layer generated in a grinding process that is performed between an etching process and a polishing process to meet the demands for minimization of a semiconductor device formed on a silicon wafer and fine layout of the silicon wafer, achieves high flatness with minimum polishing in the polishing process, and prevents metal contamination occurring in a wafer fabrication process.

### SUMMARY OF THE INVENTION

In order to achieve the above-mentioned objects, a method for manufacturing a high flatness silicon wafer comprises (S21) slicing a silicon single crystal ingot to produce a wafer; (S22) chamfering an edge of the wafer sliced from the ingot; (S23) lapping the edge-chamfered wafer; (S24) etching the lapped wafer; (S25) grinding the etched wafer; (S26) slight-etching the ground wafer using an alkali aqueous solution to remove a surface degraded layer generated on the ground wafer; (S27) polishing one or two surfaces of the slight-etched wafer; and (S28) cleaning the polished wafer.

Preferably, the grinding process (S25) is performed on one or two surfaces of the etched wafer using a polywheel made from a mixture of a ceramic bond and fine diamond particles. Preferably, in the grinding process (S25) using the polywheel, the diamond particles used in making the polywheel have a granule size of 0.2 to 1.0 μm. Preferably, in the grinding process (S25) using the polywheel, the polywheel has rotation speed of 900 to 1500 rpm and movement speed of 0.1 to 0.3 μm/s. And, preferably the wafer being ground has rotation speed of 150 to 250 rpm.

Preferably, the alkali aqueous solution used as a slight-etching solution in the slight-etching process (S26) is any one material selected from the group consisting of NaOH and KOH. At this time, preferably NaOH selected as the alkali aqueous solution in the slight-etching process (S26) has concentration of 48 to 55%. Meanwhile, preferably NaOH selected as the alkali aqueous solution in the slight-etching process (S26) has 0.2 ppb (parts per billion) or less of Ni, 1 ppb or less of Cu, 20 ppb or less of Fe, 20 ppb or less of Al and chloride with purity of 300 ppm or less. Preferably, the slight-etching process (S26) is performed at temperature of 55 to 75° C. Preferably, the slight-etching process (S26) is performed to remove 3 to 4 μm in thickness of an upper surface of the wafer. The slight-etching process (S26) is performed while agitating the wafer dipped in the slight-etching solution, or performed using a high circulating flow or a diffusion plate.

### BRIEF DESCRIPTION OF THE DRAWINGS

Hereinafter, preferred embodiments of the present invention will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present invention on the basis of the principle that the inventor is allowed to define terms appropriately for the best explanation.

FIG. 1 is a flow chart illustrating a conventional method for manufacturing a silicon wafer.

FIG. 2 is a flow chart illustrating a method for manufacturing a high flatness silicon wafer according to the present invention.

FIG. 3 is a photograph illustrating a surface of a silicon wafer after a slight-etching process according to change in concentration of NaOH used as a slight-etching solution in the slight-etching process according to the present invention.

FIG. 4 is a graph illustrating change in removal and gloss according to change in concentration of NaOH used as the slight-etching solution in the slight-etching process according to the present invention.

FIG. 5 is a photograph illustrating surface roughness and texture according to temperature of the present invention.

FIG. 6 is a cross-sectional view illustrating an apparatus for manufacturing a high purity slight-etching solution according to the present invention.

FIG. 7 is a photograph illustrating pit damage of a wafer surface after the slight-etching process using the diffusion plate according to the present invention.

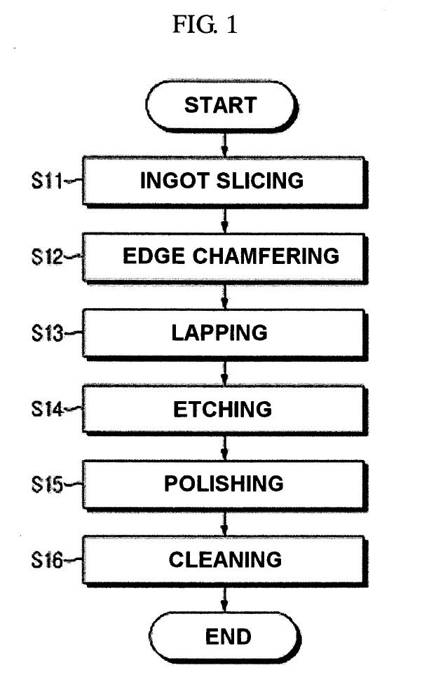

### DESCRIPTION OF THE PREFERRED EMBODIMENT

Hereinafter, preferred embodiments of the present invention will be described in detail with reference to the accompanying drawings.

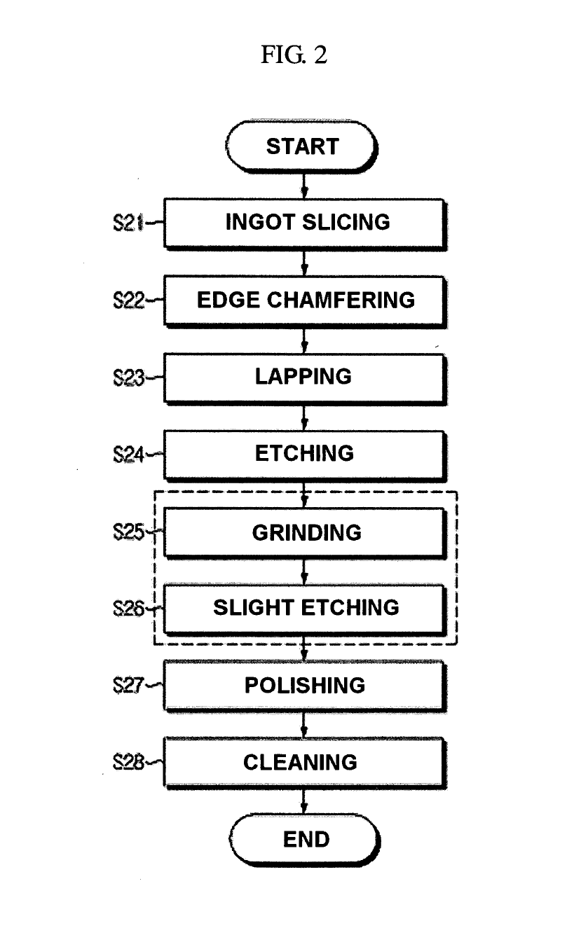

FIG. 2 is a flow chart illustrating a method for manufacturing a high flatness silicon wafer according to the present invention.

The method for manufacturing a high flatness silicon wafer according to the present invention comprises a slicing process for slicing a silicon single crystal ingot to produce a wafer (S21), a chamfering process for chamfering an edge of the wafer (S22), a lapping process for lapping the edge-chamfered wafer (S23), an etching process for etching the lapped wafer (S24), a grinding process for grinding one or two surfaces of the etched wafer (S25), a slight-etching process using an alkali aqueous solution for removing a surface degraded layer generated on the ground wafer (S26), a polishing process for polishing one or two surfaces of the slight-etched wafer (S27) and a cleaning process for cleaning the polished wafer (S28).

The steps (S21) to (S24), (S27) and (S28) are similar to those of the conventional method for manufacturing a silicon wafer, and may be performed by a well-known technique, therefore their description is omitted. The present invention is characterized that the grinding process (S25) is performed on one or two surfaces of the wafer before the polishing process (S27) and the slight-etching process (S26) is performed to effectively remove the surface degraded layer generated on the wafer in the grinding process (S25).

The grinding process (S25) is performed on one or two surfaces of the etched wafer using a polywheel made from a mixture of a ceramic bond and fine diamond particles. At this time, preferably the diamond particles used in making the polywheel have a granule size of 0.2 to 1.0 μm. Preferably, in the grinding process (S25), the polywheel has rotation speed of 900 to 1500 rpm and movement speed of 0.1 to 0.3 μm/s. And, preferably the wafer being ground has rotation speed of 150 to 250 rpm.

The slight-etching process (S26) follows the grinding process (S25). Preferably, the alkali aqueous solution used as a slight-etching solution in the slight-etching process (S26) is any one material selected from the group consisting of NaOH and KOH. At this time, preferably NaOH selected as the alkali aqueous solution in the slight-etching process (S26) has concentration of 48 to 55%.

In the case that the concentration of NaOH is less than the above-mentioned minimum, it is not preferable because surface roughness is reduced. In the case that the concentration is more than the above-mentioned maximum, it is not preferable because costs increase according to high concentration, but an etching effect in proportion to cost is insignificant. And, a freezing point increases according to high concentration, and thus it makes delivery, movement and use of products difficult. Further, an etching rate is lowered according to high concentration, thereby reducing productivity. As the concentration of the slight-etching solution increases, texture size is reduced, and removal and gloss are reduced. However, in the case that the concentration of the slight-etching solution is more than a predetermined level, the above-mentioned problems may occur.

Meanwhile, preferably NaOH selected as the alkali aqueous solution in the slight-etching process has 0.2 ppb (parts per billion) or less of Ni, 1 ppb or less of Cu, 20 ppb or less of Fe, 20 ppb or less of Al and chloride with purity of 300 ppm or less. The exemplary purity can minimize the likelihood that gate design rule and electrical characteristic may change due to bulk and surface contamination of the wafer. Preferably, the slight-etching process (S26) is performed at temperature of 55 to 75° C. Preferably, the slight-etching process (S26) is performed to remove 3 to 4 μm in thickness of an upper surface of the wafer. The slight-etching process (S26) is performed while agitating the wafer dipped in the slight-etching solution, or performed using a high circulating flow or a diffusion plate.

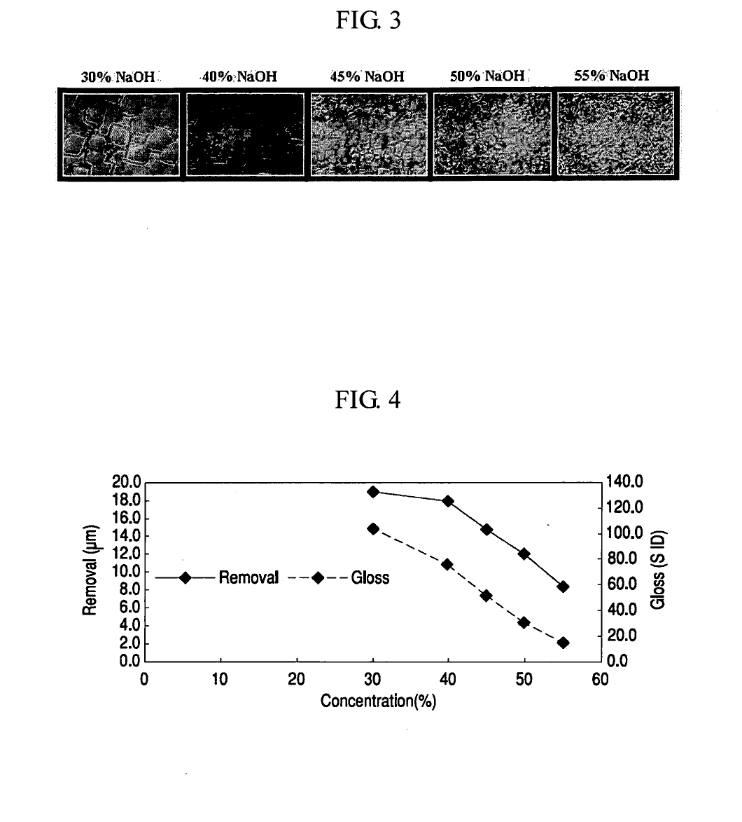

FIGS. 3 and 4 show the relationship between concentration and removal and gloss in the slight-etching process when NaOH used as the slight-etching solution has concentration of 45% or less and concentration of 50% or more.

FIG. 3 is a photograph illustrating the surface of the silicon wafer after the slight-etching process according to change in concentration of NaOH used as the slight-etching solution in the slight-etching process. Referring to FIG. 3, when the concentration of NaOH is each 30%, 40% and 45%, the surface of the wafer has relatively large texture size and poor surface roughness, which may be prone to a source of pit reject. When the concentration of NaOH is each 50% and 55%, the surface of the wafer has relatively small texture size and good surface roughness.

FIG. 4 is a graph illustrating change in removal and gloss according to change in concentration of NaOH used as the slight-etching solution in the slight-etching process according to the present invention. Referring to FIG. 4, as the concentration of NaOH increases, removal and gloss reduce. That is, if the concentration of NaOH increases, it spends much time in etching the wafer with the required removal of 20 μm and gloss is lowered to reduce the quality of products.

Preferably, the slight-etching process is performed at temperature of 55 to 75° C. In the case that the slight-etching temperature is less than the above-mentioned minimum, it is not preferable because a slight-etching reaction is poor, and consequently it requires much time to perform the slight-etching process. In the case that the slight-etching temperature is more than the above-mentioned maximum, it is not preferable because high temperature and reaction heat cause damage and contamination to equipment, and a source of metal contamination increases due to high temperature.

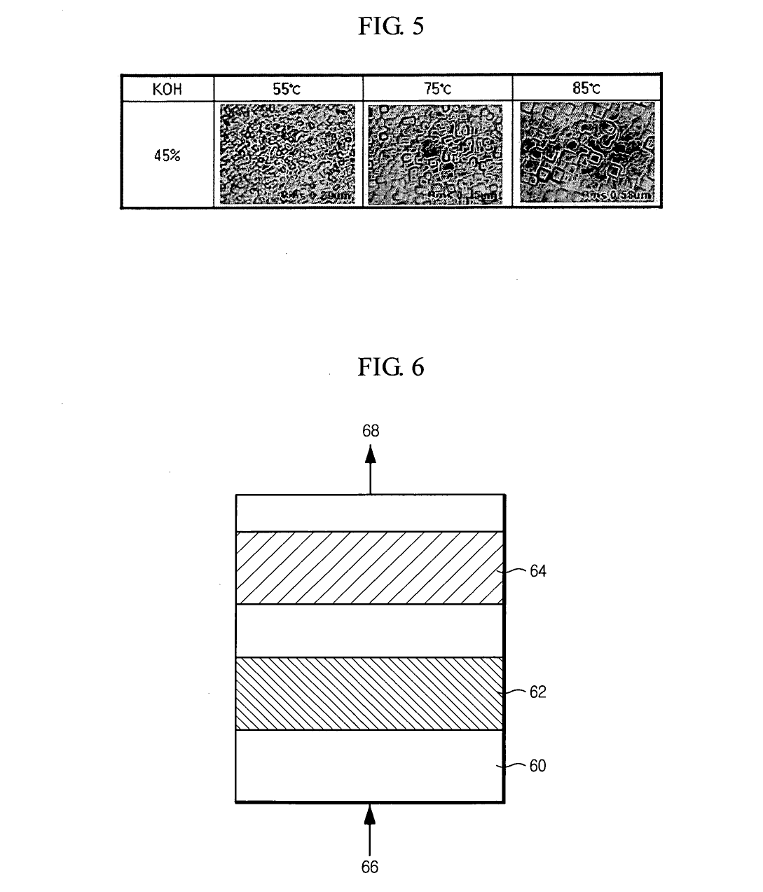

FIG. 5 is a photograph illustrating surface roughness and texture according to temperature of the present invention. As shown in FIG. 5, when removal conditions are 10 μm, as the temperature is lower, the surface of the wafer exhibits better surface roughness and finer texture.

Preferably, the slight-etching process is performed to remove 3 to 4 μm in thickness of an upper surface of the wafer. In the case that the thickness of the wafer removed by the slight-etching process is less than the above-mentioned minimum, it is not preferable because wheel debris in a previous DSG process (developed by Diamond Semiconductor Group, Inc.) is not completely removed, thereby causing faults. In the case that the thickness of the wafer removed by the slight-etching process is more than the above-mentioned maximum, it is not preferable because the wafer is influenced by flatness degradation.

Preferably, NaOH selected as the alkali aqueous solution in the slight-etching process has 0.2 ppb (parts per billion) or less of Ni, 1 ppb or less of Cu, 20 ppb or less of Fe, 20 ppb or less of Al and chloride with purity of 300 ppm or less.

A general alkali etching process is an anisotropic etching process, and is performed under high temperature. The wafer is exposed to metal contamination due to various heavy metals contained in KOH or NaOH. To solve the metal contamination problem, it is required to use an etching solution with even higher purity than a conventional etching solution. It is known that a high purity NaOH may be manufactured by electrolysis or electrochemical method. The electrolysis is useful in controlling the content of impurities to 1 ppb or less, but requires high costs. Therefore, a method for manufacturing a high purity etching solution using an activated carbon filter is suggested.

An apparatus for manufacturing a high purity slight-etching solution is described in detail with reference to FIG. 6.

FIG. 6 is a cross-sectional view illustrating the apparatus for manufacturing a high purity slight-etching solution according to the present invention. Referring to FIG. 6, the apparatus for manufacturing a high purity slight-etching solution comprises a refining pipe body 60 having a hollow inner portion, a lower portion which a slight-etching solution before refinement is flowed into (in the direction of an arrow 66) and an upper portion which a slight-etching solution after refinement is flowed out from (in the direction of an arrow 68), a lower activated carbon filter 62 contacted with the lower portion of the refining pipe body 60 and packed with fibroid materials in its hollow inner portion, and an upper activated carbon filter 64 contacted with the upper portion of the refining pipe body 60 and packed with fibroid materials in its hollow inner portion. The lower activated carbon filter 62 is spaced away from the upper activated carbon filter 64. The alkali etching solution, NaOH before refinement is flowed into the lower portion of the refining pipe body and goes through the lower activated carbon filter 62 and the upper activated carbon filter 64 packed with fibroid materials in the refining pipe body 60. Various kinds of heavy metals contained in NaOH are removed through filtering, and thus considerable amount of metal impurities are removed to obtain a high purity etching solution. As compared with the conventional electrolysis or electrochemical method, the present invention does not require a complicated equipment or high costs. Therefore, the present invention can manufacture a NaOH etching solution with a desired purity in a simple manner.

Meanwhile, the slight-etching process prevents deterioration of the slight-etching solution caused by a reaction pressure field which is generated between adjacent wafers when agitating up and down the wafer dipped in the slight-etching solution and, and prevents flatness degradation caused by temperature inclination. Generally, an agitation height of the wafer is preferably 100 to 300 mm, but if there is no procedural limitation, as agitation is made larger, the above-mentioned problems are solved more effectively. The above-mentioned agitating method may be replaced by a high circulating flow method. The high circulating flow method minimizes influence of the reaction pressure field by a heating reaction between the wafer and the compound to achieve high flatness of the wafer. At this time, preferably a circulating amount is 50 to 70 LPM. In the slight-etching process, a diffusion plate may be used for a suitable laminar flow, so that more uniform etching may be achieved. At this time, the diffusion plate has thickness of 10 to 30 mm, and a hole size of 3 to 7 mm.

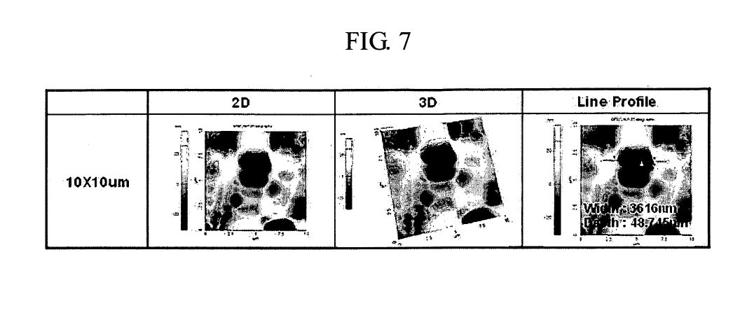

FIG. 7 is a photograph illustrating pit damage of a wafer surface after the slight-etching process using the diffusion plate according to the present invention.

Referring to FIG. 7, it was observed that a wafer surface of 10 μm width and 10 μm length has pit damage of a scan size of 3,616 nm width and 48.75 nm depth as shown in a line profile. It is found that pit damage of the wafer surface was prevented about 50% as compared with the conventional method. As pit damage is smaller, flatness of the wafer is better, and thus the present invention advantageously reduces a polishing amount in the polishing process.

It should be understood that the detailed description and specific examples, while indicating preferred embodiments of the invention, are given by way of illustration only, since various changes and modifications within the spirit and scope of the invention will become apparent to those skilled in the art from this detailed description.

### APPLICABILITY TO THE INDUSTRY

The present invention can remove effectively a surface degraded layer generated in a grinding process that is performed between an etching process and a polishing process to meet the demands for minimization of a semiconductor device formed on a silicon wafer and fine layout of the silicon wafer, achieve high flatness with minimum polishing in the polishing process, and prevent metal contamination occurring in a wafer fabrication process. And, the present invention can manufacture a high purity slight-etching solution simply and economically, that is used in manufacturing the high flatness silicon wafer.

What is claimed is:

1. A method for manufacturing a high flatness silicon wafer, comprising:
(S21) slicing a silicon single crystal ingot to produce a wafer;
(S22) chamfering an edge of the wafer sliced from the ingot;
(S23) lapping the edge-chamfered wafer;
(S24) etching the lapped wafer;
(S25) grinding the etched wafer;
(S26) slight-etching the ground wafer using an alkali aqueous solution to remove a surface degraded layer generated on the ground wafer;
(S27) polishing one or two surfaces of the slight-etched wafer; and
(S28) cleaning the polished wafer.

2. The method for manufacturing a high flatness silicon wafer according to claim 1,
wherein the grinding step (S25) is performed on one or two surfaces of the etched wafer using a polywheel made from a mixture of a ceramic bond and fine diamond particles.

3. The method for manufacturing a high flatness silicon wafer according to claim 2,
wherein, in the grinding step (S25) using the polywheel, the diamond particles have a granule size of 0.2 to 1.0 μm.

4. The method for manufacturing a high flatness silicon wafer according to claim 2,
wherein, in the grinding step (S25) using the polywheel, the polywheel has rotation speed of 900 to 1500 rpm and movement speed of 0.1 to 0.3 μm/s, and the wafer being ground has rotation speed of 150 to 250 rpm.

5. The method for manufacturing a high flatness silicon wafer according to claim 2,
wherein, in the slight-etching step (S26), the alkali aqueous solution is any one material selected from the group consisting of NaOH and KOH.

6. The method for manufacturing a high flatness silicon wafer according to claim 5,
wherein, in the slight-etching step (S26), NaOH used as the alkali aqueous solution has concentration of 48 to 55%.

7. The method for manufacturing a high flatness silicon wafer according to claim 5,
wherein, in the slight-etching step (S26), NaOH used as the alkali aqueous solution has 0.2 ppb (parts per billion) or less of Ni, 1 ppb or less of Cu, 20 ppb or less of Fe, 20 ppb or less of Al and chloride with purity of 300 ppm or less.

8. The method for manufacturing a high flatness silicon wafer according to claim 2,
wherein the slight-etching step (S26) is performed at 55 to 75° C.

9. The method for manufacturing a high flatness silicon wafer according to claim 2,
wherein the slight-etching step (S26) is performed to remove 3 to 4 μm in thickness of an upper surface of the wafer.

10. The method for manufacturing a high flatness silicon wafer according to claim 2,
wherein the slight-etching step (S26) is performed while agitating the wafer dipped in the alkali aqueous solution.

11. The method for manufacturing a high flatness silicon wafer according to claim 2,
wherein the slight-etching step (S26) is performed using a high circulating flow.

12. The method for manufacturing a high flatness silicon wafer according to claim 2,
wherein the slight-etching step (S26) is performed using a diffusion plate.
